(19) United States
(12) Patent Application Publication
(10) Pub. No.: US 2016/0064073 A1
(43) Pub. Date: Mar. 3, 2016

(54) RESISTANCE CHANGE TYPE MEMORY DEVICE

(71) Applicant: KABUSHIKI KAISHA TOSHIBA, Tokyo (JP)

(72) Inventors: Nao MATSUOKA, Yokohama Kanagawa (JP); Kosuke HATSUDA, Tokyo (JP); Mariko IIZUKA, Yokohama Kanagawa (JP); Katsuhiko HOYA, Yokohama Kanagawa (JP); Hiroyuki TAKENAKA, Kamakura Kanagawa (JP)

(73) Assignee: KABUSHIKI KAISHA TOSHIBA, Tokyo (JP)

(21) Appl. No.: 14/582,099

(22) Filed: Dec. 23, 2014

Related U.S. Application Data
(60) Provisional application No. 62/044,706, filed on Sep. 2, 2014.

(51) Int. Cl. G11C 13/00; G11C 11/16

(52) U.S. Cl. CPC G11C 13/004; G11C 13/0069; G11C 11/1675; G11C 11/1673

(57) ABSTRACT

A resistance change type memory device according to an embodiment includes a plurality of memory elements; a first to a fourth bit lines connected to the plurality of memory elements, respectively; a first to a fourth transistors connected at their one ends to the first to the fourth bit lines, respectively; a fifth transistor connected at its one end to the other ends of the first and second transistors; a sixth transistor connected at its one end to the other ends of the third and fourth transistors; and a fifth bit line connected to the other ends of the fifth and sixth transistors.

### CROSS REFERENCE TO RELATED APPLICATIONS

This application claims the benefit of U.S. Provisional Application No. 62/044,706, filed Sep. 2, 2014, the entire contents of which are incorporated herein by reference.

### FIELD

Embodiments described herein relate generally to a resistance change type memory device.

### BACKGROUND

As a memory device, there is known, for instance, a resistance change type memory device using a resistance change element.

### BRIEF DESCRIPTION OF THE DRAWINGS

FIG. 1 illustrates an example of a circuit configuration of a memory device according to a first embodiment.

FIG. 2 illustrates an example of a layout of banks of the memory device according to the first embodiment.

FIG. 3 illustrates an example of a circuit configuration of first and second local column switches of the memory device according to the first embodiment.

FIG. 4 illustrates an example of a layout of the first and second local column switches having the circuit configuration of FIG. 3.

FIG. 5A schematically illustrates a configuration example of a first transistor of the memory device according to the first embodiment.

FIG. 5B schematically illustrates another configuration example of the first transistor of the memory device according to the first embodiment.

FIG. 5C schematically illustrates a configuration example of a second transistor of the memory device according to the first embodiment.

FIG. 6 illustrates an example of a layout of banks of a memory device according to a second embodiment.

FIG. 7 illustrates an example of a circuit configuration of first and second local column switches of the memory device according to the second embodiment.

FIG. 8 schematically illustrates a configuration example of a memory element included in the memory devices according to the embodiments.

### DETAILED DESCRIPTION

A memory device, such as a resistance change type memory device, includes a plurality of memory elements. The plural memory elements are connected to bit lines, respectively. Each bit line is provided with transistors. These plural transistors are included in a transistor group. When an operation, such as write and read, is executed for a specific memory element, the transistor of the bit line, to which the memory element of an operation target is connected, is turned on. Thereby, the target bit line is electrically connected to a sense amplifier and write driver (SA/WD).

In recent years, the number of memory elements included in the memory device has been increasing. Thus, in order to increase the number of memory elements which are connected to one SA/WD, there is a case in which, for example, a global bit line extending from the SA/WD is branched into a plurality of bit lines, and connected to the memory elements. However, in some cases, with such branching of bit lines, the number of transistors included in the transistor group increases, and the size of the transistor group increases. Besides, there is a case in which a leak current via a transistor, which is in the OFF state, increases.

According to embodiments to be described below, at least one of the above-described issues can be solved. Specifically, a resistance change type memory device according to an embodiment includes a plurality of memory elements; a first to a fourth bit lines connected to the plurality of memory elements, respectively; a first to a fourth transistors connected at their one ends to the first to the fourth bit lines, respectively; a fifth transistor connected at its one end to the other ends of the first and second transistors; a sixth transistor connected at its one end to the other ends of the third and fourth transistors; and a fifth bit line connected to the other ends of the fifth and sixth transistors.

This embodiment will be described hereinafter with reference to the accompanying drawings. In the drawings, the same parts are denoted by like reference numerals. Further, an overlapping description is given where necessary.

In the description below, when the word “connection” is simply used, this means physical connection, and the meaning includes direct connection or indirect connection via some other element. When the word “electrical connection” is used, this means an electrically conductive state, and the meaning includes direct connection or indirect connection via some other element.

### First Embodiment

A memory device according to the present embodiment will now be described. The memory device according to this embodiment is, for example, a resistance change type memory device using a resistance change element as a memory element.

(1) Configuration Example of Resistance Change Type Memory Device

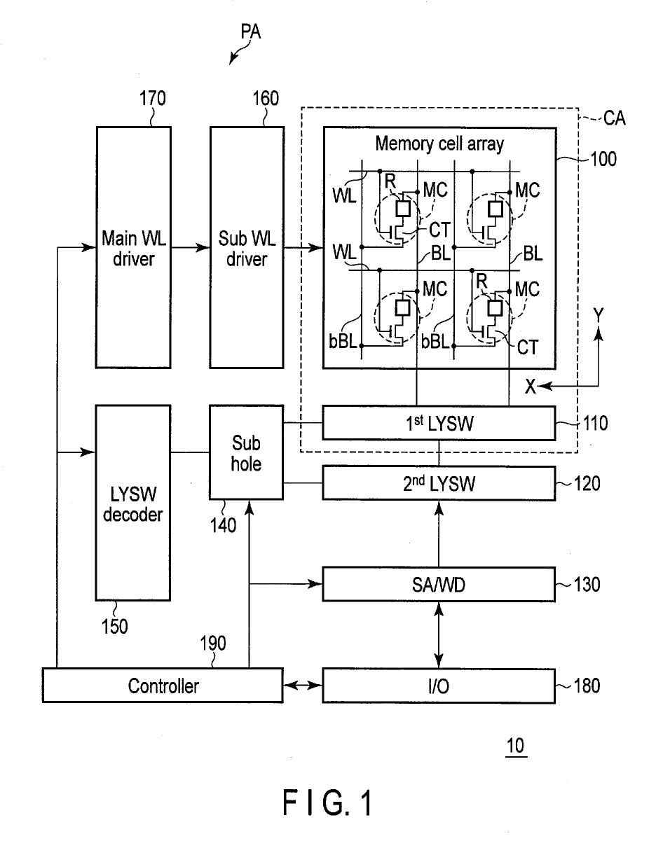

Referring to FIG. 1, a description is given of a configuration example of a resistance change type memory device 10 functioning as the memory device according to the embodiment. FIG. 1 illustrates an example of a circuit configuration of the memory device according to this embodiment.

As illustrated in FIG. 1, the resistance change type memory device 10 includes a memory cell array 100, a first local column switch (LYSW) 110, a second local column switch (LYSW) 120, a sense amplifier and write driver (SA/WD) 130, a sub-hole 140, a LYSW decoder 150, a sub-word line driver 160, a main word line driver 170, an input/output circuit 180, and a controller 190. The resistance change type memory device 10 includes at least one set of the memory cell array 100, the first local column switch 110, and the second local column switch 120. The resistance change type memory device 10 may include a plurality of such sets.

The memory cell array 100 includes a plurality of memory cells MC. The plural memory cells MC are arranged in a matrix in the memory cell array 100. A plurality of memory cells MC, which are arranged in each row in an X direction (row direction), are connected to a common word line WL of a plurality of word lines WL extending in the X direction in the memory cell array 100. A plurality of memory cells MC, which are arranged in each column in a Y direction (column direction), are connected to a common bit line pair BL, bBL, of a plurality of bit line pairs BL, bBL, which extend in the Y direction in the memory cell array 100.

The memory cell MC includes a resistance change element R functioning as a memory element, and a cell transistor CT. The resistance change element R is configured such that the resistance change element R can store data by a variation of a resistance state thereof. The resistance change element R is configured such that data is written or read out by various electric currents being supplied to the resistance change element R. The cell transistor CT is connected in series to the resistance change element R, and configured to control the supply and stop of an electric current to the resistance change element R. The cell transistor CT is turned on, thereby starting current supply, and the cell transistor CT is turned off, thereby stopping current supply. The cell transistor CT is composed as, for example, a buried gate transistor which has a gate buried in the substrate. At one end of the resistance change element R, the memory cell MC is connected to one of the bit line pair BL, bBL, for example, the bit line BL. Further, at one end of the current path of the cell transistor CT, the memory cell MC is connected to the other of the bit line pair BL, bBL, for example, the bit line bBL. Furthermore, at the gate of the cell transistor CT, the memory cell MC is connected to the word line WL. However, in the structure of the cell transistor CT, the gate and the word line WL are not distinguished, and the gate of the cell transistor CT is substantially identical to the word line WL.

The first and second local column switches 110, 120 function as switches which electrically connect a specific memory cell MC of the plural memory cells MC to the SA/WD 130. The first and second local column switches 110, 120 are connected to the plural bit lines BL extending from the memory cell array 100. The first local column switch 110 is configured to electrically connect a specific bit line BL to the second local column switch 120 by an ON/OFF operation. The second local column switch 120 is configured to electrically connect a specific bit line BL to a global bit line by an ON/OFF operation. A structure including the first and second local column switches 110, 120 is, in some cases, referred to as a multiplexer. As described above, the multiplexer of the present embodiment is composed of two stages, namely the first local column switch 110 and the second local column switch 120. The structure of the first and second local column switches 110, 120 will be described later.

In the meantime, the bit lines bBL of the plural bit line pairs BL, bBL may also be led out from, for example, the other side of the memory cell array 100, and may be connected to an SA/WD 130 via other local column switches.

The sub-hole 140 generates control signals to the first and second local column switches 110, 120, and supplies them to the first and second local column switches 110, 120.

The LYSW decoder 150 controls the first and second local column switches 110, 120, based on an address signal.

The SA/WD 130 supplies an electric current to a specific memory cell MC via the global bit line and the bit line BL, and executes write and read for the memory cell MC (resistance change element R). To be more specific, the write driver of the SA/WD 130 executes write in the memory cell MC. The sense amplifier of the SA/WD 130 executes read from the memory cell MC.

The sub-word line driver 160 and the main word line driver 170 are connected to a plurality of word lines WL extending from the memory cell array 100. The sub-word line driver 160 and the main word line driver 170 are hierarchically constructed, and supply a signal to the word line WL to which an operation-target memory cell MC is connected.

The input/output circuit 180 sends various signals, which have been received from the outside, to the controller 190 and SA/WD 130, and sends various information from the controller 190 and the SA/WD 130 to the outside.

The controller 190 is connected to the SA/WD 130, the sub-hole 140, the LYSW decoder 150, the main word line driver 170, and the input/output circuit 180. The controller 190 controls the SA/WD 130, the sub-hole 140, the LYSW decoder 150, and the main word line driver 170 in accordance with signals which have been received by the input/output circuit 180 from the outside.

In the resistance change type memory device 10, the memory cell array 100 is disposed in a cell area CA. The first local column switch 110 is also disposed in the cell area CA. On the other hand, the second local column switch 120 is disposed in a peripheral area PA where the other structural parts, i.e. the SA/WD 130, the sub-hole 140, the LYSW decoder 150, the each word line driver 160, 170, the input/output circuit 180, and the controller 190, are disposed. In some cases, the cell area CA is referred to as a core area, compared to the peripheral area PA.

Further, in the resistance change type memory device 10, in some cases, a structural element group, which can store data, is referred to as a bank. Specifically, the bank includes at least the memory cell array 100, the first and second local column switches 110, 120, and the SA/WD 130. The bank may also include the sub-hole 140 and the sub-word line driver 160.

(2) Layout of Resistance Change Type Memory Device

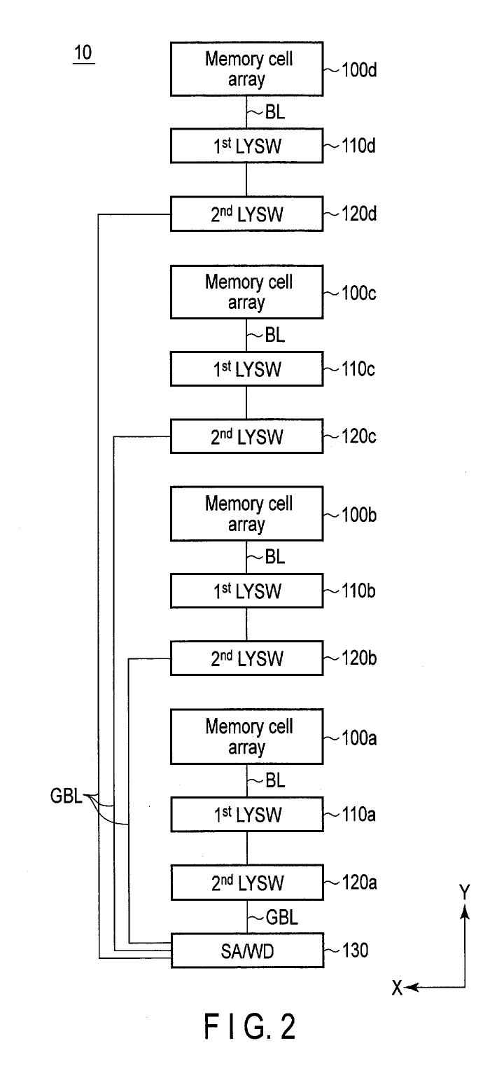

Referring to FIG. 2, a description is given of an example of a layout of structural elements of the resistance change type memory device 10. FIG. 2 illustrates an example of the layout of banks of the memory device according to this embodiment. FIG. 2 illustrates the example in which the resistance change type memory device 10 includes a plurality of sets of the memory cell array 100, the first local column switch 110, and the second local column switch 120.

In the layout example of FIG. 2, a plurality of memory cell arrays 100 are connected to a common SA/WD 130. On one side in the Y direction of each memory cell array 100, for example, on the SA/WD 130 side, the first local column switch 110 and the second local column switch 120 are arranged in the named order. A bit line BL of each memory cell array 100 is led out on the one side in the Y direction, and connected to the first local column switch 110 disposed on the one side of each memory cell array 100. The first local column switch 110 is connected to the second local column switch 120, and is controlled by the second local column switch 120.

Specifically, a bit line BL of a memory cell array 100a is connected to a first local column switch 110a, and is further connected to a second local column switch 120a via the first local column switch 110a. The second local column switch 120a and the SA/WD 130 are connected via a global bit line GBL. A bit line BL of a memory cell array 100b is connected to a first local column switch 110b, and is further connected to a second local column switch 120b via the first local column switch 110b. The second local column switch 120b and the SA/WD 130 are connected via a global bit line GBL. The same applies to a memory cell array 100c, a first local column switch 110c and a second local column switch 120c. The same applies to a memory cell array 100d, a first local column switch 110d and a second local column switch 120d.

As described above, the respective first and second local column switches 110, 120 are disposed near the associated memory cell arrays 100. Specifically, the first and second local column switches 110, 120 are disposed, not on the side near the SA/WD 130, but on the side near the associated memory cell arrays 100. To be more specific, for example, the first local column switch 110 neighbors the associated memory cell array 100, and the second local column switch 120 neighbors the first local column switch 110.

In other words, these structural elements are arranged, for example, from the SA/WD 130 side, in the order of the second local column switch 120a, the first local column switch 110a, the memory cell array 100a, the second local column switch 120b, the first local column switch 110b, the memory cell array 100b . . . . In this manner, the respective first and second local column switches 110, 120, and the memory cell arrays 100 are disposed on one side of the SA/WD 130.

Incidentally, in FIG. 2, for the purpose of convenience, one bit line BL and one global bit line GBL, which connects the respective structural elements, are illustrated. In the actual configuration, however, the number of bit lines BL and the number of global bit lines GEL are not limited to this example. The memory cell array 100, the first local column switch 110, and the second local column switch 120 may be connected by a plurality of bit lines BL. The second local column switch 120 and the SA/WD 130 may be connected by a plurality of global bit lines GBL. In a case where a plurality of global bit lines GBL are connected to the SA/WD 130, the SA/WD 130 may include a plurality of sense amplifier units. Each global bit line GBL is connected to, for example, each sense amplifier unit in a one-to-one correspondence.

Further, in this embodiment, the direction of lead-out of each global bit line GBL is not necessarily as shown in FIG. 2. FIG. 2 does not mean that the global bit lines GBL are led out, for example, from a plurality of directions of the SA/WD 130. The global bit lines GBL are led out from one side of the SA/WD 130, for example, from the side on which the memory cell array 100, etc. are disposed.

(3) Configuration Example of First and Second Local Column Switches

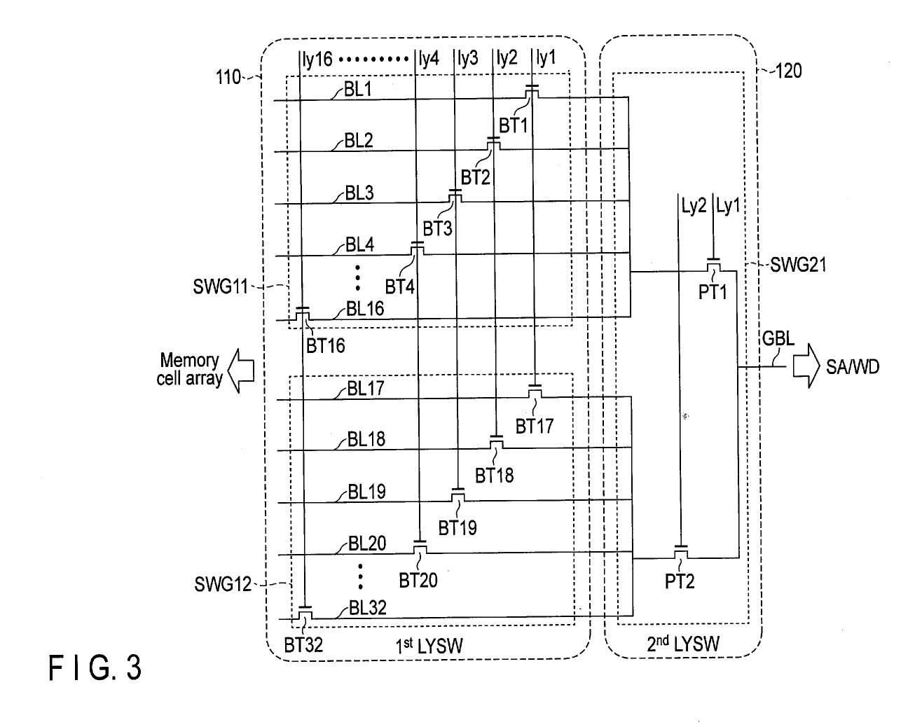

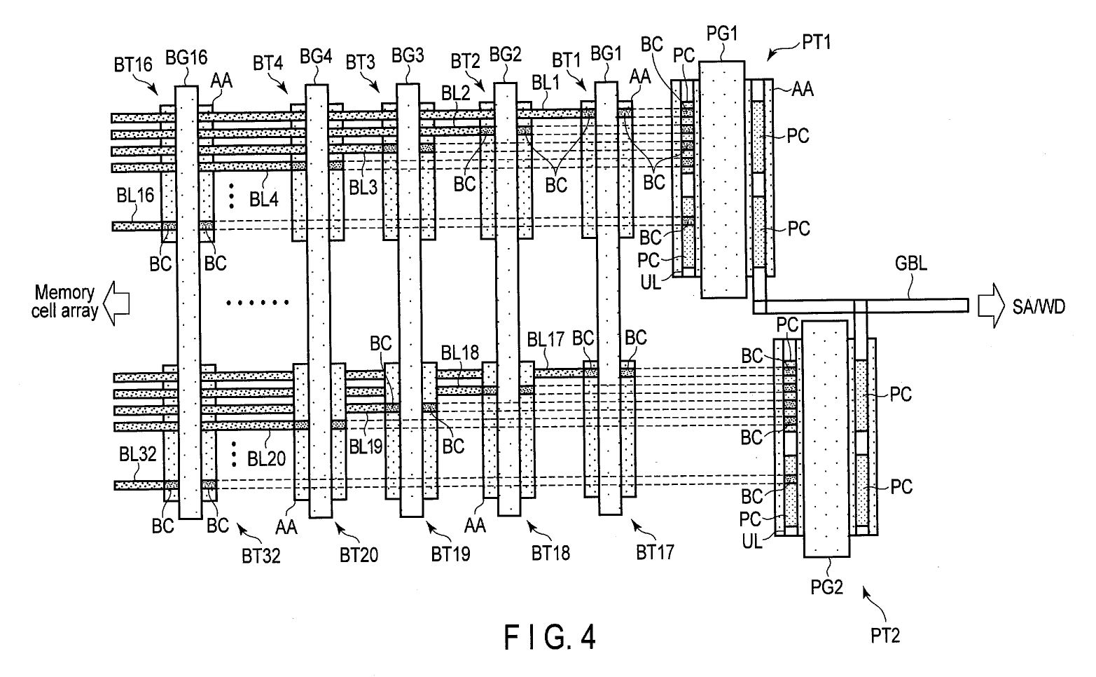

Referring to FIG. 3 and FIG. 4, a configuration example of the first and second local column switches 110, 120, which are connected to the common memory cell array 100, is described. FIG. 3 illustrates an example of the circuit configuration of the first and second local column switches of the memory device according to the present embodiment. FIG. 4 illustrates an example of the layout of the first and second local column switches having the circuit configuration of FIG. 3.

As described above, the individual memory cells MC are connected to the SA/WD 130 via a plurality of bit lines (BL1 to BL32) and a global bit line GBL to which these bit lines BL are connected. In one memory cell array 100, for example, only one memory cell MC becomes an operation target, that is, only one bit line BL is electrically connected to the global bit line GBL. The first and second local column switches 110, 120 are provided on a path extending from each memory cell MC to the SA/WD 130, that is, on a path of the bit lines BL and the global bit line GBL, and narrow down the bit lines BL to one bit line which is to be electrically connected to the global bit line GBL.

As illustrated in FIG. 3 and FIG. 4, the first local column switch 110 includes, for example, two first transistor groups SWG1 (SWG11, SWG12). The first transistor group SWG11 includes, for example, 16 first transistors BT (BT1 to BT16). The first transistor group SWG12 includes, for example, 16 first transistors BT (BT17 to BT32). The first transistors BT (BT1 to BT32) are provided on the associated bit lines BL (BL1 to BL32) in a one-to-one correspondence. Specifically, for example, the first transistor BT1 is provided on the bit line BL1, and the first transistor BT17 is provided on the bit line BL17.

As illustrated in FIG. 4, each first transistor BT is, for example, composed as a buried gate transistor in which a gate BG (BG1 to BG16) functioning as a control node, is individually buried in the substrate. In the buried gate transistor, a channel is formed at a periphery of the buried gate BG. Thus, the buried gate transistor can easily be reduced in size, while a sufficient channel length is secured.

Diffusion layers AA are formed at a periphery of the buried gate BG, and the diffusion layers AA, which are formed on both sides of the gate BG, function as a source and a drain. Each bit line BL is divided at a part of the gate BG of the first transistor BT provided on the bit line BL. An end portion of one divided bit line BL is connected to one diffusion layer AA (e.g. source side) of the gate BG by a contact BC. An end portion of the other divided bit line BL is connected to the other diffusion layer AA (e.g. drain side) of the gate BG by a contact BC. Thereby, when the first transistor BT is in the OFF state, the divided bit lines BL are electrically shut off and no electric current flows between these bit lines BL. When the first transistor BT is in the ON state, the divided bit lines BL are rendered conductive.

The respective first transistors BT1 to BT16 of the first transistor group SWG11 and the respective first transistors BT17 to BT32 of the first transistor group SWG12 constitute sets which share the gates BG (BG1 to BG16) functioning as control nodes. Specifically, for example, the first transistor BT1 of the first transistor group SWG11 and the first transistor BT17 of the first transistor group SWG12 share the gate BG1. Further, the first transistor BT2 of the first transistor group SWG11 and the first transistor BT18 of the first transistor group SWG12 share the gate BG2.

As illustrated in FIG. 3, the gates BG (BG1 to BG16) of the first transistor BT are supplied with corresponding signals ly (ly1 to ly16), and thereby the respective first transistors BT are configured to be turned on or off. At this time, the respective transistors BT1 to BT16 of the first transistor group SWG11 and the respective transistors BT17 to BT32 of the first transistor group SWG12 share the gates BG1 to BG16, and receive the common signals ly1 to ly16. Specifically, for example, the common signal ly1 is supplied to the first transistor BT1 of the first transistor group SWG11 and the first transistor BT17 of the first transistor group SWG12. Further, the common signal ly2 is supplied to the first transistor BT2 of the first transistor group SWG11 and the first transistor BT18 of the first transistor group SWG12. By these signals ly1 to ly16, any one of the first transistors BT1 to BT16 of the first transistor SWG11 and any one of the first transistors BT17 to BT32 of the first transistor SWG12 are turned on. In this manner, each first transistor group SWG1 functions, for example, as a 16:1 switch which narrows down 16 bit lines BL to one.

As illustrated in FIG. 3 and FIG. 4, the second local column switch 120 includes, for example, one second transistor group SWG21. The second transistor group SWG21 includes, for example, two second transistors PT (PT1, PT2). The second transistor PT is composed, for example, as a planar transistor in which a gate PG is formed on the substrate. The bit lines BL1 to BL16 are connected to one end of a current path of the second transistor PT1. The bit lines BL17 to BL32 are connected to one end of a current path of the second transistor PT2. In other words, in the configuration example of FIG. 3, the first transistor groups SWG1 are connected to the respective second transistors PT in a one-to-one correspondence. Two branched global bit lines GBL are connected to the other ends of the current paths of the second transistors PT1, PT2, respectively.

As illustrated in FIG. 4, to be more specific, diffusion layers AA are formed in a surface portion of the substrate, under the gate PG of the second transistor PT. The diffusion layers AA function as a source and a drain, with the gate PG being interposed. Each bit line BL is connected, by a contact BC, PC, to the diffusion layer AA on one side of the gate PG, that is, on the first transistor group SWG1 side. Further, each bit line BL is connected to an upper-layer wiring UL. The branched global bit line GBL is connected, by a contact PC, to the diffusion layer AA on the other side of the gate PG, that is, on the side opposite to the first transistor group SWG1. Thereby, the plural bit lines BL are integrated into the global bit line GBL via the second transistor PT. Specifically, the plural bit lines BL are aggregated into the global bit line GBL via the second transistor PT. In other words, the second transistor PT branches the global bit line GBL into the plural bit lines BL.

As illustrated in FIG. 3, the gates PG (PG1, PG2) of the second transistors PT are supplied with corresponding signals Ly (Ly1, Ly2), and thereby each second transistor PT is configured to be turned on or off. Specifically, a signal Ly1 is delivered to the second transistor PT1, and a signal Ly2 is delivered to the second transistor PT2. By these signals Ly1, Ly2, either of the second transistors PT1, PT2 is turned on, and either of the first transistor groups SWG11, SWG12 is selected. Specifically, one of the two first transistors BT, which have been turned on, is selected. Thereby, the bit line BL, on which this first transistor BT is provided, is electrically connected to the SA/WD 130 via the global bit line GBL. In this manner, the second transistor group SWG2 functions as a 2:1 switch which narrows down, for example, two bit lines BL into one.

In the above manner, by the second transistor group SWG2, one of the first transistor groups SWG11, SWG12 is selected. Thus, even if the gates BG of the first transistors BT are shared between the first transistor groups SWG11, SWG12, bit lines BL can be narrowed down to a specific one.

In the above description, both lines, which are divided by the first transistor BT, are bit lines BL. However, for example, the line located on the side opposite to the memory cell array 100, that is, the line between the first transistor BT and the second transistor PT, may be regarded as a line different from the bit line BL. Further, the two lines, into which the global bit line GBL is branched, may be regarded as parts of the global bit line GBL, or may be regarded as lines different from the global bit line GBL.

Further, the interval (pitch) in the actual configuration between the bit lines BL16, BL17 in FIG. 4 may be narrower than the interval illustrated in FIG. 4. The interval between the bit lines BL16, BL17 may be identical to the interval between other bit lines BL, for instance, between bit lines BL1, BL2, or between bit lines BL17, BL18. All of the pitches between the bit lines BL1 to BL32 may be a pitch that is the limit of lithography (a minimum line width).

(4) Configuration Example of First Transistor

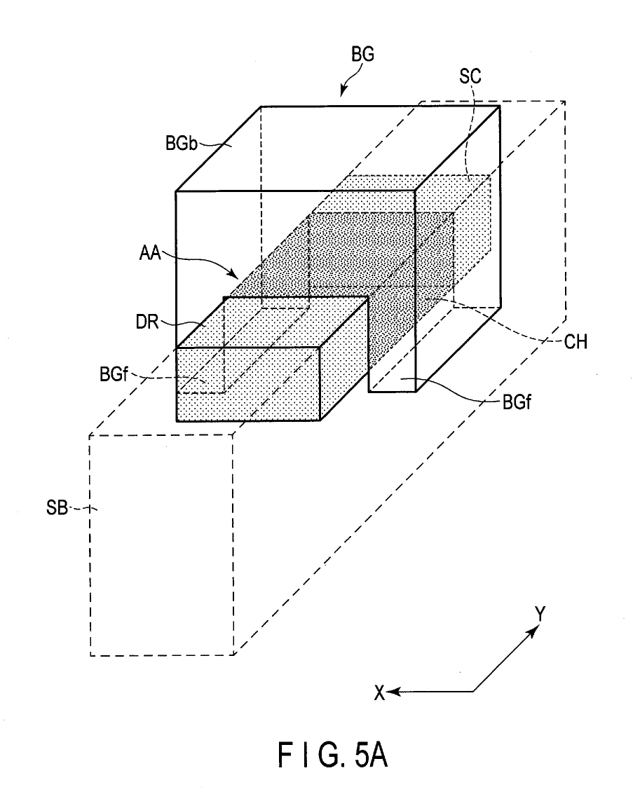

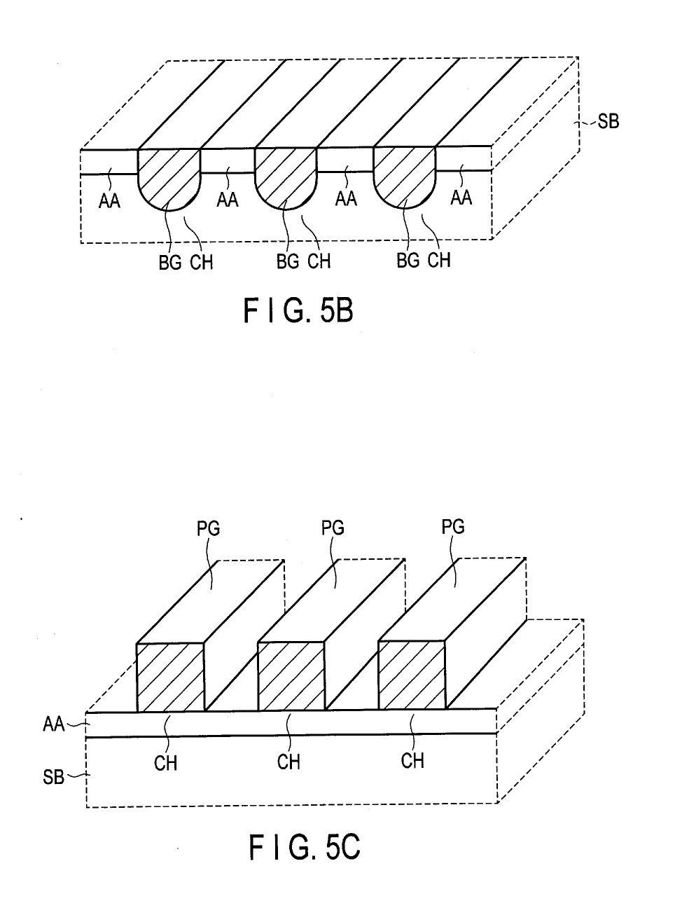

Referring to FIG. 5A, a description is given of a configuration example of the first transistor BT of the first local column switch 110 included in the resistance change type memory device 10. FIG. 5A schematically illustrates a configuration example of the first transistor of the memory device according to the present embodiment. The first transistor BT illustrated in FIG. 5A is composed, for example, as a buried gate transistor having a saddle fin structure.

As illustrated in FIG. 5A, the first transistor BT includes a substrate SB, a diffusion layer AA, and a gate BG.

The substrate SB is divided in the X direction by a device isolation region (not shown). Each of the areas of the substrate SB divided by the device isolation region includes the diffusion layer AA. The diffusion layer AA is provided in a surface portion of the substrate SB.

The gate BG extends in the X direction over the plural areas of the divided substrate SB. In one area of the substrate SB, the gate BG has a saddle fin structure surrounding an upper surface and side surfaces of a part of the diffusion layer AA. Specifically, the gate BG includes a body BGb disposed on the upper surface of the diffusion layer AA, and two feet BGf disposed on both side surfaces in the X direction of the diffusion layer AA. The two feet BGf are buried in the substrate SB.

That portion of the diffusion layer AA, which is in contact with the gate BG, functions as a channel CH. The other regions of the diffusion layer AA, that is, both sides of the gate BG in the Y direction, function as a source SC and a drain DR.

In the meantime, FIG. 5B illustrates an example in which the first transistor BT is composed as a buried gate transistor. The first transistor BT illustrated in FIG. 5B includes a substrate SB, a diffusion layer AA provided in a surface layer of the substrate SB, and a gate BG buried in the substrate SB via a gate insulation film (not shown). FIG. 5C illustrates an example in which the second transistor PT is composed as a planar transistor. The second transistor PT illustrated in FIG. 5C includes a substrate SB, a diffusion layer AA provided in a surface layer of the substrate SB, and a gate PG disposed on the substrate SB. In the structure of each of the first transistor BT and the second transistor PT, an interface between the gate BG, PT and the substrate SB functions as a channel CH.

As described above, since the first transistor BT is composed as the buried gate transistor, a channel length is secured in the limited area. Further, since the first transistor BT is composed as the buried gate transistor having the saddle fin structure, a channel width is secured in the limited area. Thus, by adopting, for example, the buried gate transistor or the buried gate transistor with the saddle fin structure as the first transistor BT, the first transistor BT can easily be reduced in size.

In the present embodiment, for example, like the cell transistor CT of the memory cell MC, the first transistor BT is composed as the buried gate transistor. Each of the first transistor BT and the cell transistor CT may be composed as the saddle fin-type buried gate transistor.

Specifically, the first transistor BT has substantially the same structure as, for example, the cell transistor CT, and is formed by substantially the same fabrication process. In other words, the first transistor BT includes, for example, one of a plurality of structures formed as the cell transistor CT.

In the present embodiment, the first transistor BT, which is composed as the buried gate transistor or the saddle fin-type buried gate transistor, may be smaller than the second transistor PT composed as the planar transistor.

In this embodiment, for example, both the first transistor ET and the cell transistor CT may be provided in the cell area CA of the resistance change type memory device 10. The second transistor PT may be provided in the peripheral area PA of the resistance change type memory device 10.

Incidentally, each of the gate BG of the first transistor BT and the gate PG of the second transistor PT is also called a word line. As described above, the gate of the cell transistor CT is substantially identical to the word line WL in FIG. 1.

(5) Operation of Resistance Change Type Memory Device

Referring to FIG. 1 and FIG. 3, an operation example of the resistance change type memory device 10 is described. The operation to be described below is mainly executed by the SA/WD 130, the sub-hole 140, the LYSW decoder 150, the main word line driver 170, etc., in accordance with the control of the controller 190 of FIG. 1 which has received instructions from the outside.

In operations of write and read for memory cells MC, a bit line BL, which is connected to a memory cell MC that is an operation target, is electrically connected to the SA/WD 130. A bit line bBL, which is paired with this bit line BL, is electrically connected to the SA/WD 130 in the write operation, and is connected to a sink circuit (not shown) and is set at a ground potential in the read operation. Further, the potential of the word line WL, which is connected to the memory cell MC of the operation target, is set at H level by the word line drivers 160, 170. Thereby, the cell transistor CT included in this memory cell MC is turned on.

By the above, a write current or a read current flows from the SA/WD 130 to the memory cell MC, and a write operation or a read operation is executed for the resistance change element R included in the memory cell MC.

In the above, the first and second local column switches 110, 120 control the electrical connection between the bit lines BL and the SA/WD 130.

Specifically, in the first and second local column switches 110, 120, the first transistor BT and the second transistor PT are individually turned on or off in accordance with signals from the sub-hole 140 and the LYSW decoder 150. The following is a concrete example of a case in which a bit line BL3 is electrically connected to the SA/WD 130.

A signal ly3 of H level is supplied to a gate BG3 of a first transistor BT3 provided on the bit line BL3. Thereby, the first transistor BT3 is turned on, and divided bit lines BL3, which are divided by the first transistor BT3, are rendered conductive. A first transistor BT19 shares the gate BG3 with the first transistor BT3. Thus, the signal ly3 of H level is also supplied to the first transistor BT19. Thereby, the first transistor BT19 is also turned on, and divided bit lines BL19, which are divided by the first transistor BT19, are rendered conductive.

The first transistor group SWG11, in which the first transistor BT3 is included, is connected to the second transistor PT1. A signal Ly1 of H level is supplied to the gate PG1 of the second transistor PT1. Thereby, the second transistor PT1 is turned on, and the bit line BL3 and the global bit line GBL are electrically connected via the second transistor PT1. On the other hand, the second transistor PT2 is not turned on, and the bit line BL19 and the global bit line GBL are kept in an electrically shut-off state.

By the above, the bit line BL3 and the SA/WD 130 are electrically connected.

In this manner, according to the above-described configuration of the first and second local column switches 110, 120, both the first transistor BT3 and the first transistor BT19 are turned on by the signal ly3 of H level. The turned-on first transistor BT3 and the first transistor BT19 are narrowed down to either of them by the second transistor group SWG21.

(6) Advantageous Effects of Present Embodiment

According to the present embodiment, the following one or plural advantageous effects are obtained.

(A) According to this embodiment, the first transistors BT of the first transistor groups SWG1 are provided, in a one-to-one correspondence, on the bit lines BL which connect the resistance change elements R and the global bit line GBL. The second transistors PT of the second transistor group SWG2 are provided between the plural bit lines BL and the global bit line GBL, and branch the global bit line GBL into the plural bit lines BL.

In this manner, by the first transistor groups SWG1 and the second transistor group SWG2, the number of bit lines BL is narrowed down, and the narrowed-down bit line BL is connected to the SA/WD 130. Thereby, a greater number of bit lines BL can be connected to one SA/WD 130. Thus, the number of SA/WDs 130, which are mounted on the resistance change type memory device 10, can be reduced, and the chip area of the resistance change type memory device 10 can be reduced.

(B) According to the above configuration (A), the resistance change type memory device 10 includes a two-stage configuration of the first transistor groups SWG1 and the second transistor group SWG2. Thereby, the number of transistors, which are connected to the global bit line GBL, can be reduced.

In the above-described configuration example of FIG. 3 and FIG. 4, the transistors, which are connected to the global bit line GBL without intervention of other transistors, etc., are only the second transistors PT1, PT2. By contrast, when the transistor groups do not have the two-stage configuration, that is, when a 32:1 switch, for instance, is used, 32 transistors are connected to the global bit line.

According to this embodiment, for example, compared to the case in which the transistors of all bit lines are connected to the global bit line without intervention of other transistors, etc., the junction capacitance of the first transistors BT, which is added to the global bit line GBL, can be reduced. Thus, the time needed for data read, etc. of the memory cell MC can be reduced.

Further, according to this embodiment, for example, compared to the case in which the transistors of all bit lines are connected to the global bit line without intervention of other transistors, etc., a leak current via turned-off first transistors BT can be reduced. Thus, the data read margin can sufficiently be secured.

(C) According to this embodiment, the gate BG is shared between at least one first transistor BT connected to one second transistor PT1 of the plural second transistors PT1 and PT2 included in one second transistor group SWG21, and at least one first transistor BT connected to the other second transistor PT2. Specifically, for example, the first transistor BT1 and the first transistor BT17 share the gate BG1.

In this manner, the gates BG of the first transistors BT are shared between the first transistor groups SWG11 and SWG12, and thereby the number of gates BG of first transistors BT can be reduced. For example, a 32:1 switch, which narrows down 32 bit lines BL to one can be obtained by 18 gates in total. Therefore, the area of disposition of the first transistor groups SWG1 can be reduced, and the chip area of the resistance change type memory device 10 can be reduced.

(D) According to this embodiment, the first transistor BT is a buried gate transistor or a saddle fin-type buried gate transistor. Thereby, the first transistor BT can be reduced in size, and the chip area of the resistance change type memory device 10 can be reduced. The number of first transistors BT is greater than the number of second transistors PT. The reduction in size of the first transistors BT has a great influence on the chip area of the resistance change type memory device 10.

(E) According to this embodiment, the first transistor BT and the cell transistor CT are buried gate transistors or saddle fin-type buried gate transistors. Thereby, the first transistor BT and the cell transistor CT can be fabricated by substantially the same process. Thus, there is no need to separately perform design and manufacture of the first transistor BT, and the first transistor BT can easily be manufactured. Besides, the manufacturing cost can be reduced.

(F) According to this embodiment, the second transistor PT is a planar transistor.

As described above, the first transistor BT is constructed as, for example, a buried gate transistor, and can be fabricated in a smaller size than the second transistor PT which is constructed as a planar transistor. However, due to the reduction in size of the first transistor BT, a leak current tends to easily occur when the first transistor BT is in the OFF state.

Further, as described above, the first transistor BT is fabricated by substantially the same process as the cell transistor CT. Thus, in some cases, it is difficult to independently optimize the structure of the first transistor BT, such as the gate length, gate width or size, and the characteristics of the transistor.

On the other hand, as regards the second transistor PT constructed as the planar transistor, the design restrictions, such as those for the first transistor BT, are relatively relaxed. In the second transistor PT, the reduction in size is not easy, but a leak current, for instance, does not easily occur. Thus, a leak current occurring in the first transistor BT can be shut off, and the influence of the leak current on the SA/WD 130 can be suppressed.

### Second Embodiment

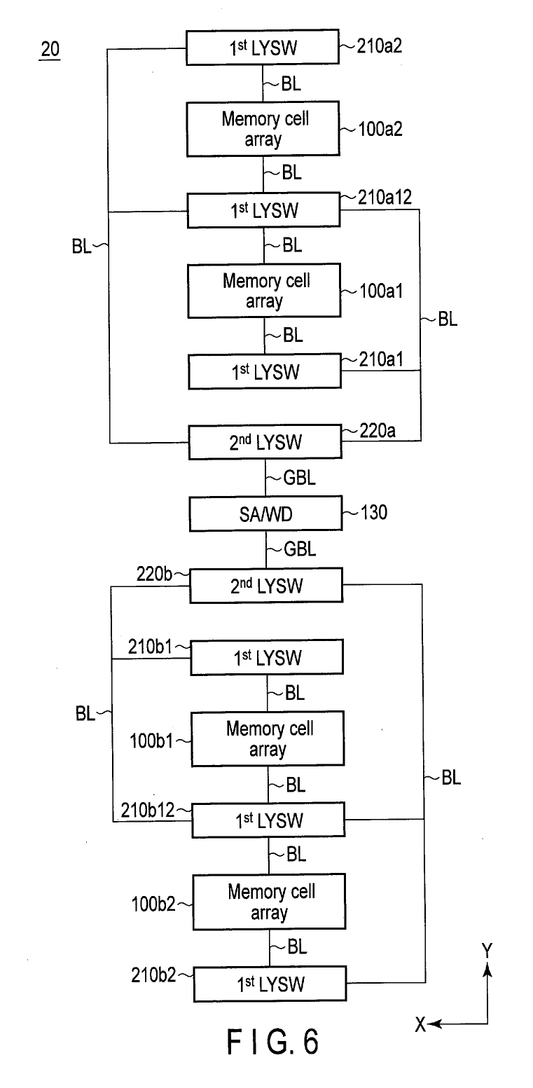

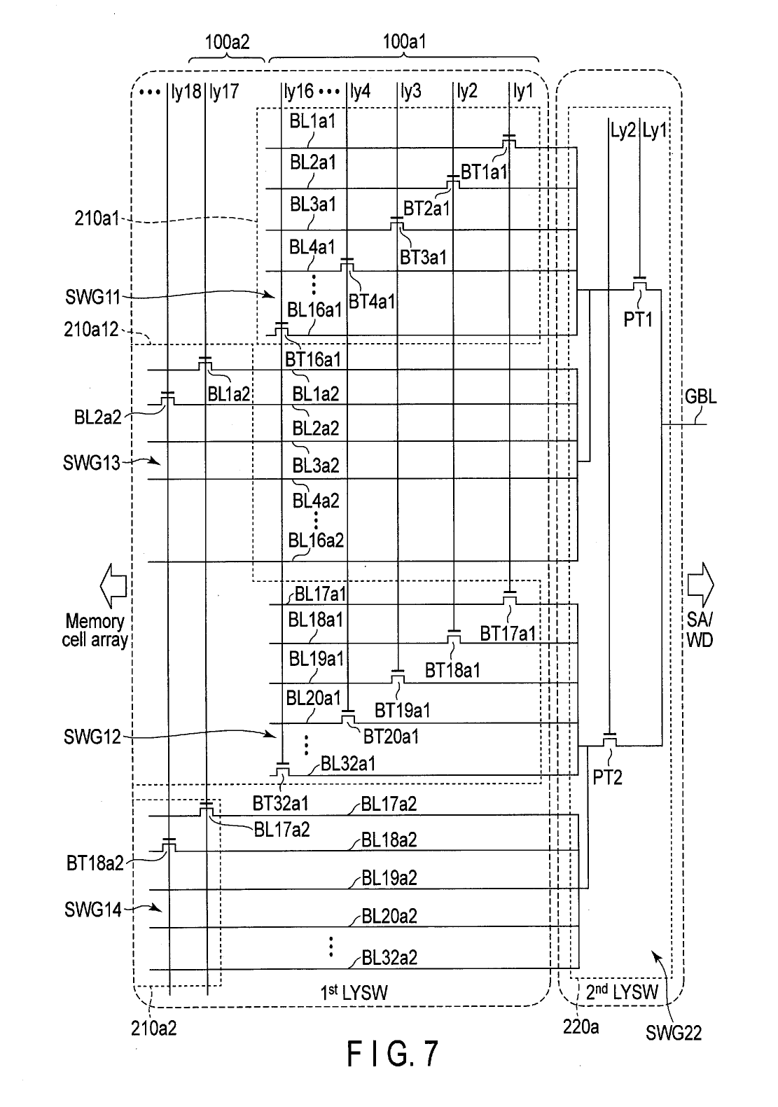

The present embodiment is described with reference to FIG. 6 and FIG. 7. A resistance change type memory device 20 of this embodiment differs from the above-described embodiment in that first local column switches 210 are connected to memory cells MC from both sides in one direction of a memory cell array 100, and that a second local column switch 220 is commonly connected to a plurality of memory cell arrays 100.

(1) Layout of Resistance Change Type Memory Device

FIG. 6 illustrates an example of a layout of banks of the memory device according to the present embodiment.

In the layout example of FIG. 6, first local column switches 210 are disposed on both sides in the Y direction of each memory cell array 100. The bit lines BL of each memory cell array 100 are led out to both sides in the Y direction, and are connected to the first local column switches 210 which are disposed on both sides of each memory cell array 100. To be more specific, of the plural bit lines BL of each memory cell array 100, for example, bit lines BL of even-numbered columns are led out to one side and connected to the first local column switch 210 on the one side. Of the plural bit lines BL of each memory cell array 100, for example, bit lines BL of odd-numbered columns are led out to the other side and connected to the first local column switch 210 on the other side.

Specifically, the bit lines BL of a memory cell array 100a1 are connected, for example, at a fifty-fifty ratio, to first local column switches 210a1 and 210a12. The bit lines BL of a memory cell array 100a2 are connected, for example, at a fifty-fifty ratio, to first local column switches 210a12 and 210a2.

In other words, the first local column switch 210a1 is connected to, for example, one half of the plural bit lines BL of the memory cell array 100a1. The first local column switch 210a12 is connected to the other half of the plural bit lines BL of the memory cell array 100a1 (the bit lines BL which are not connected to the first local column switch 210a1). Further, the first local column switch 210a12 is connected to, for example, one half of the plural bit lines BL of the memory cell array 100a2. The first local column switch 210a2 is connected to the other half of the plural bit lines BL of the memory cell array 100a2 (the bit lines BL which are not connected to the first local column switch 210a12).

These first local column switches 210a1, 210a12 and 210a2 are connected to a second local column switch 220a and are controlled by the second local column switch 220a.

Similarly, the bit lines BL of a memory cell array 100b1 are connected, for example, at a fifty-fifty ratio, to first local column switches 210b1 and 210b12. The bit lines BL of a memory cell array 100b2 are connected, for example, at a fifty-fifty ratio, to first local column switches 210b12 and 210b2. These first local column switches 210b1, 210b12 and 210b2 are connected to a second local column switch 220b and are controlled by the second local column switch 220b.

As described above, the second local column switch 220a is commonly used by the plural memory cell arrays 100a and the plural first local column switches 210a. The second local column switch 220b is commonly used by the plural memory cell arrays 100b and the plural first local column switches 210b. The second local column switches 220a, 200b are connected to a common SA/WD 130 by global bit lines GBL, and are disposed on both sides in the Y direction of the SA/WD 130. Specifically, the global bit lines GBL are connected to the SA/WD 130 from both sides of the SA/WD 130.

The respective first local column switches 210 are disposed near the associated memory cell arrays 100. The respective second local column switches 220 are disposed near the SA/WD 130. Specifically, the first local column switch 210 is disposed, not on the side near the SA/WD 130, but on the side near the associated memory cell array 100. The second local column switch 220 is disposed, not on the side near the memory cell array 100, but on the side near the SA/WD 130.

To be more specific, the first local column switch 210a1 neighbors the memory cell array 100a1, and the first local column switch 210a2 neighbors the memory cell array 100a2. The first local column switch 210a12 neighbors the memory cell arrays 100a1, 100a2. The first local column switch 210b1 neighbors the memory cell array 100b1, and the first local column switch 210b2 neighbors the memory cell array 100b2. The first local column switch 210b12 neighbors the memory cell arrays 100b1, 100b2. Each of the second local column switches 220a, 200b neighbors the SA/WD 130.

In other words, these structural elements are arranged, for example, from one side of the SA/WD 130, in the order of the second local column switch 220a, the first local column switch 210a1, the memory cell array 100a1, the first local column switch 210a12, the memory cell array 100a2, the first local column switch 210a2 . . . . Further, for example, from the other side of the SA/WD 130, the structural elements are arranged in the order of the second local column switch 220b, the first local column switch 210b1, the memory cell array 100b1, the first local column switch 210b12, the memory cell array 100b2, the first local column switch 210b2 . . . .

In this manner, the first and second local column switches 210, 220 and the memory cell arrays 100 are disposed on both sides of the SA/WD 130. Further, the SA/WD 130 may be distributively arranged in banks of the resistance change type memory device 20. Specifically, the number of memory cell arrays 100 connected to one SA/WD 130 may be reduced and, on both sides of this SA/WD 130, the associated first and second local column switches 210, 220, and the memory cells 100 may be arranged. The distributive arrangement refers to a state in which a plurality of SA/WDs 130 with such arrangements are provided in the banks.

Incidentally, in FIG. 6, for the purpose of convenience, one bit line BL and one global bit line GBL, which connect the respective structural elements, are illustrated. Further, in this embodiment, the direction of lead-out of bit lines BL, which connect the first and second local column switches 210, 220, is not necessarily as shown in FIG. 6. The bit lines BL, which connect the first and second local column switches 210, 220, are led out from one side of the second local column switch 220, for example, from the side on which the first local column switch 210 is disposed.

(2) Configuration Example of First and Second Local Column Switches

FIG. 7 illustrates an example of a circuit configuration of the first and second local column switches of the memory device according to the present embodiment. In the above-described example of FIG. 6, the first and second local column switches 210a, 220a and the first and second local column switches 210b, 220b, which are disposed on both sides of the SA/WD 130, have the same circuit configurations. In FIG. 7, the first local column switches 210a1, 210a12, 210a2 and the second local column switch 220a are illustrated.

As illustrated in FIG. 7, the first local column switch 210a includes first transistor groups SWG13, SWG14, in addition to the first transistor groups SWG11, SWG12. The first transistor groups SWG11, SWG12 are provided, for example, on bit lines (BL1a1 to BL32a1) which are connected to the memory cells MC of the memory cell array 100a1. The first transistor groups SWG13, SWG14 are provided, for example, on bit lines (BL1a2 to BL32a2) which are connected to the memory cells MC of the memory cell array 100a2. Specifically, the first transistor group SWG11 belongs to the first local column switch 210a1. The first transistor groups SWG12, SWG13 belong to the first local column switch 210a12. The first transistor group SWG14 belongs to the first local column switch 210a2.

The first transistor groups SWG13, SWG14 have the same configuration as the first transistor groups SWG11, SWG12, that is, the same structural elements and connection modes as the configuration that has been described above with reference to FIG. 3. Specifically, the first transistor group SWG13 includes, for example, 16 first transistors BT (BT1a2 to BT16a2). The first transistors BT (BT1a2 to BT16a2) are provided on the associated bit lines BL (BL1a2 to BL16a2) in a one-to-one correspondence. The first transistor group SWG14 includes, for example, 16 first transistors BT (BT17a2 to BT32a2). The first transistors BT (BT17a2 to BT32a2) are provided on the associated bit lines BL (BL17a2 to BL32a2) in a one-to-one correspondence.

The first transistors BT of the first transistor groups SWG13, SWG14 have the same configuration as the first transistors BT of the first transistor groups SWG11, SWG12, that is, the same configuration as the above-described first transistors BT1 to BT32 illustrated in FIG. 4. Like the above-described first transistors BT1 to BT32, the first transistors BT of the first transistor groups SWG13, SWG14 are constructed as buried gate transistors or saddle fin-type buried gate transistors. The first transistors BT of the first transistor group SWG13 and the first transistors BT of the first transistor group SWG14 share the gates functioning as control nodes. The shared gate of the first transistors BT of the first transistor groups SWG13, SWG14 is supplied with a common signal ly (ly17 to ly32) which corresponds to this individual gate.

By the signal, ly17 to ly32, which is supplied to the first transistor groups SWG13, SWG14, two transistors BT sharing the gate, among the first transistors BT1a2 to BT32a2 of the first transistor groups SWG13, SWG14, are turned on.

The second local column switch 220a includes a second transistor group SWG22. The second transistor group SWG22 includes second transistors PT1, PT2. The bit lines BL1a2 to BL16a2, in addition to the bit lines BL1a1 to BL16a1, are connected to one end of the current path of the second transistor PT1. Specifically, a plurality of first transistor groups SWG1 (two first transistor groups in the example of FIG. 7) are connected to the second transistor PT1. The bit lines BL17a2 to BL32a2, in addition to the bit lines BL17a1 to BL32a1, are connected to one end of the current path of the second transistor PT2. Specifically, a plurality of first transistor groups SWG1 (two first transistor groups in the example of FIG. 7) are connected to the second transistor PT2.

In order to electrically connect any one of the bit lines BL in the memory cell array 100a1 to the global bit line GBL, any one of the signals ly1 to ly16 is set at H level. Further, either of the second transistors PT1, PT2 is turned on. Thereby, any one of the first transistors BT of either of the first transistor groups SWG11, SWG12 is turned. As a result, one bit line BL of the bit lines BL1a1 to BL32a1 is electrically connected to the global bit line GBL.

In order to electrically connect any one of the bit lines BL in the memory cell array 100a2 to the global bit line GBL, any one of the signals ly17 to ly32 is set at H level. Further, either of the second transistors PT1, PT2 is turned on. Thereby, any one of the first transistors BT of either of the first transistor groups SWG13, SWG14 is turned. As a result, one bit line BL of the bit lines BL1a2 to BL32a2 is electrically connected to the global bit line GBL.

As described above, one of the first local column switches 210a1, 201a12, 210a2 is selected by the second local column switch 220a. Further, a specific bit line BL is selected by narrowing-down by the first local column switch 210a.

(3) Advantageous Effects of Present Embodiment

According to the present embodiment, the following one or plural advantageous effects are obtained other than the advantageous effects of the above-described embodiment.

(A) According to the present embodiment, the first transistor groups SWG1 are connected to the memory cells MC from both sides in the Y direction of the memory cell array 100. In this manner, according to this embodiment, the arrangement of first transistor groups SWG1 can be made different from that in the above-described embodiment. Thereby, the arrangement of the structural elements including the first transistor groups SWG1 can variously be altered. Therefore, the degree of freedom of layout design of banks increases, and the design of the resistance change type memory device 20, for example, becomes easier.

(B) According to this embodiment, the second transistor group SWG22 is connected to the first transistor groups SWG12, SWG13, etc., which are connected to the different memory cell arrays 100a1, 100a12.

In this manner, one second transistor group SWG2 is shared by the plural different memory cell arrays 100, and the first transistor groups SWG1 which are connected to these different memory cell arrays 100. Thereby, the number of second transistor groups SWG2 and the number of second transistors PT included therein can be reduced. Therefore, the chip area of the resistance change type memory device 20 can be reduced.

(C) According to this embodiment, the first transistor group SWG1 is disposed on the memory cell array 100 side, and the second transistor group SWG2 is disposed on the SA/WD 130 side.

The first transistor BT has substantially the same structure as, for example, the cell transistor CT, and must be disposed in the cell area CA, like the cell transistor CT.

On the other hand, the second transistor PT can be disposed, for example, in the peripheral area PA, and the restrictions on design and disposition, such as those for the first transistor BT, are relatively relaxed. Therefore, by combining the first transistors BT and the second transistors PT, the degree of freedom of layout design of banks increases, and the design of the resistance change type memory device 20, for example, becomes easier.

(D) According to this embodiment, the second transistor groups SWG2 are connected to the SA/WD 130 from both sides of the SA/WD 130. In this manner, according to this embodiment, the SA/WD 130 is disposed, for example, at the center of the plural first and second transistor groups SWG1, SWG2. Thereby, even the first transistor group SWG1, which is farthest from the SA/WD 130, can be connected to the SA/WD 130 with a relatively short wiring. It is thus possible to suppress an increase in parasitic resistance and parasitic capacitance, and to reduce noise, in the wiring between the SA/WD 130 and the first transistor groups SWG1.

In this case, the wiring length from the first transistor groups SWG1 to the second transistor group SWG2 increases. However, for example, by distributively arranging the SA/WD 130, as described above, the wiring length can be adjusted and an increase in resistance value of the wiring can be suppressed.

Furthermore, according to this embodiment, in combination with the configuration of the above (A), the layout from the memory cell array 100 to the SA/WD 130 can be made compact.

### Other Embodiments

In the above-described embodiments, the description has been given of the example in which the first transistor BT is composed of a buried gate transistor or a saddle fin-type buried gate transistor, and the second transistor PT is composed of a planar transistor. However, the embodiments are not limited to this example. Both the first transistor and the second transistor may be composed of buried gate transistors or saddle fin-type buried gate transistors. Alternatively, both the first transistor and the second transistor may be composed of planar transistors.

In the above-described embodiments, the description has been given of the example in which the gate of first transistors BT included in the first transistor groups SWG11, SWG12, etc. is shared. However, the embodiments are not limited to this example. Individual first transistors BT may have individually independent gates.

The numbers of the respective structural elements in the above-described embodiments are arbitrary, and are not limited to the above examples. The number of bit lines included in one memory cell array may not be 32. The number of first transistors included in one first transistor group may not be 16. The number of first transistor groups included in one first local column switch may be other than one or two. The number of first transistor groups, which are connected to one second transistor, may be other than one or two. The number of second transistors included in one second transistor group may not be two. The number of second transistor groups included in one second local column switch may not be one.

In the above-described embodiments, the description has been given of the example in which the resistance change type memory device 10, 20 includes the two-stage configuration of the first local column switch and the second local column switch. However, the embodiments are not limited to this example. The resistance change type memory device may include a configuration of three or more stages of local column switches.

In the above embodiments, the description has been given of the example in which the memory device is configured as the resistance change type memory device 10, 20. However, the embodiments are not limited to this example. Further, the resistance change type memory device may be, for example, a magnetic memory device such as an STT (Spin-Transfer Torque) type MRAM (Magnetoresistive Random Access Memory), or may be a ReRAM (Resistive Random Access Memory), a PRAM, or a PCRAM (Phase Change Random Access Memory). The resistance change element used in the STT-MRAM is, for example, a magnetoresistive effect element.

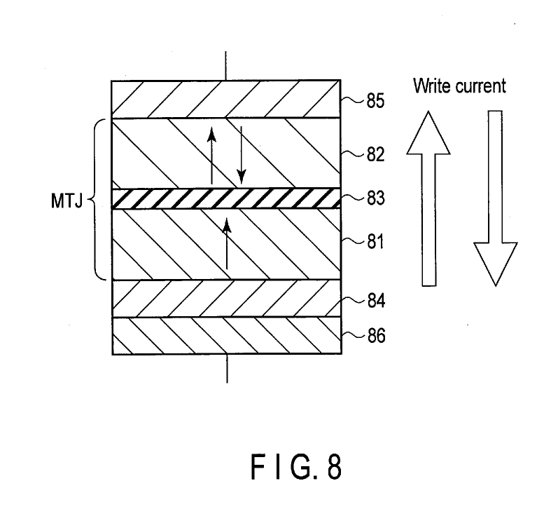

Referring to FIG. 8, a description is given of a configuration example of an MTJ (Magnetic Tunnel Junction) element functioning as a magnetoresistive effect element. FIG. 8 schematically illustrates a configuration example of a memory element included in the memory devices according to the embodiments.

The MTJ element is configured to have different resistance states in accordance with the direction of an electric current flowing through the MTJ element. A phenomenon in which a different resistance is exhibited in accordance with a state is called “magnetoresistive effect”. The MTJ element stores data by using the magnetoresistive effect.

As illustrated in FIG. 8, an MTJ (Magnetic Tunnel Junction) included in the MTJ element includes, at least, a fixed layer 81, a recording layer 82, and an insulation layer 83 between these layers. The magnetization of the fixed layer 81 is fixed by a ferromagnetic layer 84. The recording layer 82 has magnetization which changes in accordance with the direction of write current flowing through the layer. Electrode layers 85, 86 are provided in a manner to sandwich the ferromagnetic layer 84, the fixed layer 81, the recording layer 82, and the insulation layer 83.

The MTJ element exhibits different resistance states, depending on the relative relationship between the direction of magnetization of the fixed layer 81 and the direction of magnetization of the recording layer 82. Specifically, in the MTJ element, these different resistance states are associated with, for example, two values of one-bit data, depending on whether the directions of magnetization of the fixed layer 81 and the recording layer 82 are in a parallel state (low-resistance state) or in an antiparallel state (high-resistance state).

In the meantime, the MTJ element may be a vertical magnetization MTJ element having a vertical magnetization anisotropy, or a horizontal magnetization MTJ element having a horizontal magnetization anisotropy. Further, the MTJ element may be a top-free type (bottom pin type) MTJ element in which a recording layer is disposed above a fixed layer, or a bottom-free type (top pin type) MTJ element in which a recording layer is disposed below a fixed layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A resistance change type memory device comprising:
a plurality of first memory elements;
first to fourth bit lines connected to the plurality of first memory elements, respectively;
first to fourth transistors connected at first ends thereof to the first to the fourth bit lines, respectively;
a fifth transistor connected at a first end thereof to second ends of the first and second transistors;
a sixth transistor connected at a first end thereof to second ends of the third and fourth transistors;
a fifth bit line connected to second ends of the fifth and sixth transistors; and
a sense amplifier and write driver for executing write and read for the plurality of first memory elements,
wherein the second end of the fifth transistor is connected to the second end of the sixth transistor, and
wherein the fifth bit line is connected to the sense amplifier and write driver from a first side of the sense amplifier and write driver.

2. The resistance change type memory device of claim 1, wherein the first transistor and the third transistor share a control node.

3. The resistance change type memory device of claim 1, wherein:
the first transistor and the third transistor share a control node, and
the second transistor and the fourth transistor share a control node.

4. The resistance change type memory device of claim 1, wherein the first transistor is smaller than the fifth transistor.

5. The resistance change type memory device of claim 1, wherein:
the first transistor is a buried gate transistor, and
the fifth transistor is a planar transistor.

6. The resistance change type memory device of claim 5, further comprising a control transistor which is connected to one of the first memory elements, the control transistor being a buried gate transistor.

7. The resistance change type memory device of claim 1, wherein:
the first transistor is a saddle fin-type buried gate transistor, and
the fifth transistor is a planar transistor.

8. The resistance change type memory device of claim 1, wherein:
the first transistor is provided in a cell area, and
the fifth transistor is provided in a peripheral area.

9. The resistance change type memory device of claim 1, wherein:
the first memory elements are provided in a memory cell array,
the first transistor is connected to the first memory elements from a first side of the memory cell array, and
the third transistor is connected to the first memory elements from a second side of the memory cell array.

10. The resistance change type memory device of claim 9, wherein:
the first bit line is led out from the first side of the memory cell array, and
the third bit line is led out from the second side of the memory cell array.

11. The resistance change type memory device of claim 9, wherein:
the first transistor is disposed on the first side of the memory cell array, and
the third transistor is disposed on the second side of the memory cell array.

12. The resistance change type memory device of claim 1, wherein:
the first memory elements are provided in a plurality of memory cell arrays, and
the fifth transistor is connected to the first and second transistors connected to the first memory elements belonging to different memory cell arrays.

13. The resistance change type memory device of claim 12, wherein the fifth transistor is shared by the first and second transistors.

14. The resistance change type memory device of claim 12, wherein the fifth transistor is shared by the plurality of memory cell arrays.

15. The resistance change type memory device of claim 12, further comprising:
a plurality of second memory elements;
sixth to ninth bit lines connected to the plurality of second memory elements, respectively;
seventh to tenth transistors connected at first ends to the sixth to the ninth bit lines, respectively;
an eleventh transistor connected at a first end thereof to second ends of the seventh and eighth transistors;
a twelfth transistor connected at a first end to second ends of the ninth and tenth transistors; and
a tenth bit line connected to second ends of the eleventh and twelfth transistors,
wherein:
the sense amplifier and write driver execute write and read for the plurality of second memory elements,
the second end of the eleventh transistor is connected to the second end of the twelfth transistor, and
the tenth bit line is connected to the sense amplifier and write driver from a second side of the sense amplifier and write driver.

16. The resistance change type memory device of claim 15, wherein:
the fifth and sixth transistors are disposed on the first side of the sense amplifier and write driver, and
the eleventh and twelfth transistors are disposed on the second side of the sense amplifier and write driver.

17. The resistance change type memory device of claim 1, wherein:
the first memory elements are provided in a memory cell array,
the first transistor is disposed on a side of the memory cell array, and
the fifth transistor is disposed on a side of the sense amplifier and write driver.

18. The resistance change type memory device of claim 1, wherein the first memory elements are resistance change elements.

19. The resistance change type memory device of claim 1, wherein the first memory elements are magnetoresistive effect elements.
